(19) United States
(12) Patent Application Publication
(10) Pub. No.: US 2025/0021146 A1
(43) Pub. Date: Jan. 16, 2025

(54) THERMAL ISLANDING SYSTEMS

(71) Applicant: Micron Technology, Inc., Boise, ID (US)

(72) Inventors: Joseph L. Turmes, Nampa, ID (US); David A. Holmstrom, Los Gatos, CA (US)

(21) Appl. No.: 18/766,390

(22) Filed: Jul. 8, 2024

Related U.S. Application Data
(60) Provisional application No. 63/513,263, filed on Jul. 12, 2023.

(51) Int. Cl. G06F 1/20; H05K 7/20

(52) U.S. Cl. CPC G06F 1/206; H05K 7/20263; H05K 7/20781

(57) ABSTRACT

The disclosure relates to an apparatus including a plurality of first zones including a controller, a power regulation area, or both, a first heat transfer interface coupled to the plurality of first zones, a plurality of second zones including memory devices, a second heat transfer interface coupled to the plurality of second zones, and a thermal insulating barrier deployed between the plurality of first zones and the plurality of second zones.

### PRIORITY INFORMATION

This application claims the benefit of U.S. Provisional Application No. 63/513,263, filed on Jul. 12, 2023, the contents of which are incorporated herein by reference.

### TECHNICAL FIELD

Embodiments of the disclosure relate generally to memory sub-systems, and more specifically, relate to thermal islanding systems.

### BACKGROUND

A memory sub-system can include one or more memory devices that store data. The memory devices can be, for example, non-volatile memory devices and/or volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example of a computing system that includes a memory sub-system in accordance with some embodiments of the present disclosure.

FIG. 2A illustrates a view of an example of a memory sub-system in accordance with some embodiments of the present disclosure.

FIG. 2B illustrates a view of an example of an individual device included in an example of a memory sub-system in accordance with some embodiments of the present disclosure.

FIG. 2C illustrates a view of another example of an individual device included in an example of a memory sub-system in accordance with some embodiments of the present disclosure.

FIG. 3 illustrates a view of another example of a memory sub-system in accordance with some embodiments of the present disclosure.

FIG. 4 illustrates a view of yet another example of a memory sub-system in accordance with some embodiments of the present disclosure.

### DETAILED DESCRIPTION

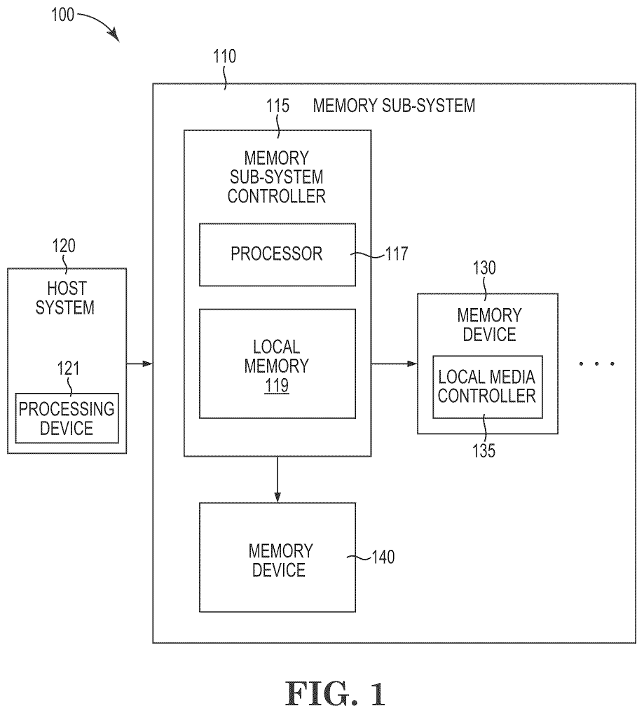

Aspects of the present disclosure are directed to thermal islanding systems such as servers which employ thermal islanding. In some embodiments, the thermal islanding systems may include a thermal islanding barrier (e.g., an air gap, a thermal insulating material, or both) in a memory sub-system. A memory sub-system can be a storage system, storage device, a memory module, or a combination of such. An example of a memory sub-system is a storage system such as a solid-state drive (SSD), a server, and/or a server employing one or more SSD's. Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system.

A memory device can be a non-volatile memory device. One example of non-volatile memory devices is a negative-and (NAND) memory device (also known as flash technology). Other examples of non-volatile memory devices are described below in conjunction with FIG. 1. A non-volatile memory device is a package of one or more dice. Each die can consist of one or more planes. Planes can be grouped into logic units (LUN). For some types of non-volatile memory devices (e.g., NAND devices), each plane consists of a set of physical blocks. Each block consists of a set of pages. Each page consists of a set of memory cells (“cells”). A cell is an electronic circuit that stores information. A block hereinafter refers to a unit of the memory device used to store data and can include a group of memory cells, a word line group, a word line, or individual memory cells. For some memory devices, blocks (also hereinafter referred to as “memory blocks”) are the smallest area that can be erased. Pages cannot be erased individually, and only whole blocks can be erased.

Each of the memory devices can include one or more arrays of memory cells. Depending on the cell type, a cell can store one or more bits of binary information, and has various logic states that correlate to the number of bits being stored. The logic states can be represented by binary values, such as “0” and “1”, or combinations of such values. There are various types of cells, such as single level cells (SLCs), multi-level cells (MLCs), triple level cells (TLCs), and quad-level cells (QLCs). For example, a SLC can store one bit of information and has two logic states, while a TLC can store multiple bits of information and has eight logic states.

Another example of a memory device can be a volatile memory device. A volatile memory device can include a memory array, which can be a dynamic random access memory (DRAM) array, SRAM array, STT RAM array, PCRAM array, TRAM array, and/or RRAM array, for instance. In general, a volatile memory device stores data while the memory device is powered but generally does not store data when the memory device is powered down or is powered off. A memory sub-system, such as a SSD, can include a combination of non-volatile memory devices and volatile memory devices.

During operation, components of a memory sub-system (e.g., a server) can experience fluctuations in thermal conditions, such as operating temperatures. For example, because electrical current is utilized to provide power to the components (e.g., memory devices, a power regulation area, controllers, etc.) of a memory sub-system, the memory sub-system and the components thereof can exhibit temperature fluctuations during operation. Such fluctuations can become more pronounced based on the type of workload the memory sub-system and the respective components thereof are subjected to. For example, some types of workloads that can be characterized by high volumes of operations can give rise to greater temperature fluctuations in the memory sub-system and the components thereof than workloads that are characterized by low volumes of operations. Further, a memory sub-system can experience temperature fluctuations based on the environment in which the memory sub-system is deployed, an amount of time the memory sub-system is continually operating, and/or a form factor of the memory sub-system, which can dictate the placement and available footprint allowable for the components of the memory sub-system to be deployed.

Although some amount of temperature fluctuation is tolerable within a memory sub-system, the memory sub-system can be adversely affected if such temperature fluctuations exceed certain thresholds. For example, if a memory sub-system is exposed to temperatures that are greater than a threshold safe operating temperature range, the memory sub-system can experience degraded performance and, in some instances, can fail.

Due to the technological evolution of memory sub-system technology, which is, at least in part driven by user (e.g., client, customer, etc.) expectations, there are constantly evolving issues regarding thermal control with respect to memory sub-systems, such as SSDs, servers, and/or servers employing one or more SSD. For example, because storage media (e.g., memory device) trends are becoming more sensitive to thermal variations given increasing power level demands and/or the implementation of ever-faster storage protocols, thermal control in a memory sub-system continues to become increasingly important in order to mitigate degraded performance and/or failures that can occur when a memory sub-system is exposed to temperatures that approach or exceed a threshold safe operating temperature range. Further, form factors for memory sub-systems and the constituent components thereof are also trending towards a reduction in size due to, for example, the increasing prevalence of compact computing devices (e.g., smartphones, phablets, tablets, laptops, etc.) which can result in more heat being generated in a smaller space.

In conventional approaches, thermal control and/or thermal mitigation in memory sub-systems generally involves spreading components of a memory sub-system, such as a SSD and/or one or more server racks, across a widest area possible to reduce the overall maximum temperature on any part of the memory sub-system. Such approaches can therefore rely on coupling the memory sub-system controller and/or application specific integrated circuits (ASICs) that perform controller functions for the memory sub-system together with the memory devices (e.g., storage media associated with the memory sub-system) and a power regulation area (e.g., power regulation circuitry to provide power to the components of the memory sub-system) on a printed circuit board (PCB). In general, a “power regulation area” refers to an area of a memory sub-system that includes circuitry or other components that are configured to provide and/or manage power (e.g., signals indicative of a voltage, a current, etc.) to operate other components of the memory sub-system. In these approaches, a heatsink, or other similar generally monolithic device(s) is provided to dissipate or otherwise spread heat across the components coupled to the PCB to mitigate adverse effects that can arise when the memory sub-system is exposed to temperatures that are greater than a threshold safe operating temperature range.

Although such approaches can allow for heat to be dissipated across the PCB thereby providing a cooling effect to some components of the memory sub-system, undesired effects may also occur. For example, by spreading the thermal load of the hottest components (e.g., power supplies, power regulation areas, and/or controllers, among others) throughout the memory sub-system and therefore to components that are generally heat sensitive (e.g., memory devices), various issues can arise. For example, an increase in the temperature and/or thermal load experienced by the memory devices as a result of heat being transferred from the hottest components to the heat sensitive components can lead to the memory devices incurring increased error rates, reduced media life, and/or undesirable cross temperature behaviors.

These undesired effects can be further pronounced in some form factor implementations (e.g., M.2 form factor architectures, U.2 form factor architectures, U.3 form factor architectures etc.) where thermal management is of utmost concern due to the constrained space available to house the components of a memory sub-system. Moreover, the undesired effects can be further pronounced in some dense architectures such as servers (e.g., a rack-mounted server) in which memory devices are located in a plurality of server racks that are co-located within the same chassis. The memory devices in the plurality of server racks may be operated independently (e.g., at the same time) and thus may produce a large amount of heat in a relatively small amount of space. In addition, due to being operated independently the memory devices may operate differently (e.g., may be subjected to varying workloads) and therefore may have different cooling considerations at a given time. Moreover, due to being co-located in the same chassis (e.g., in a stacked configuration) the plurality of server racks may not readily dissipate heat generated within the chassis. For instance, a server may include a plurality of PCB's disposed in a plurality of racks such that the racks, and the PCB's are arranged in parallel to a surface of a chassis in which each of the plurality of racks are disposed. For example, each of the racks and therefore each of the PCB's may be vertically stacked in parallel or may be co-located in a horizontal manner in parallel to the chassis.

In some approaches, thermal management can be provided through the use of multiple temperature sensors, component placement, and/or complicated firmware algorithms to maintain components of the memory sub-system within a particular thermal operating range. However, adding additional components such as multiple heat sensors and processing capability to perform the complicated firmware algorithms can further exacerbate issues associated with the limited available physical space in small form factor devices. Further, memory sub-system consumers are becoming more sophisticated in understanding that the temperature of the memory devices in a memory sub-system is generally the thermal priority and, because their data being accurately stored is of key concern, are more frequently requesting that memory sub-system operating temperature values are specified in terms of the memory device operating temperatures.

These and other trends and concerns have uncovered inadequacies in approaches that utilize conventional thermal management strategies such as the employment of a heat sink to maximize the spread of heat across the memory sub-system (e.g., across the PCB of the memory sub-system). For example, in contemporary memory sub-systems, the traditional strategy of maximizing the heat spread through the use of a heat sink can induce more complex endurance issues as the memory device(s), which generally account for only a small to moderate contribution to the heat generated by the memory sub-system, are less tolerant to the increased thermal load from other components of the memory device, such as the controller(s), power regulation area(s), power supplies, etc.

Aspects of the present disclosure address the above and other deficiencies by providing a special purpose heat sink (e.g., a thermal islanding heatsink that includes a monolithic heat sink and a thermal insulating barrier) that isolates heat transfer from the hot components (e.g., the controller(s), power regulation area(s), power supplies, etc.) to the memory devices with a thermally insulative material that is placed in between different “thermal zones” of the memory sub-system. Notably, the different “thermal zones” can include two or more different thermal zones such as a “warm zone” and a “hot zone” in the same server (e.g., on the same side of a PCB in the server) may yield improved memory server performance attributable at least to having a plurality of the same types of zones (e.g., warm zones) thermally coupled together and/or due to having different types of memory devices in different thermal zones, as detailed herein, in contrast to other approaches that do not employ thermal zones or that do not thermally couple together a plurality of the same types of thermal zones (but not different types of thermal zones) in the same device (e.g., in an individual server).

Moreover, thermally coupling together a plurality of the same type of thermal zones (e.g., warm zones) together in the same device may ensure that all the memory devices (e.g., non-volatile memory devices) in the plurality of thermally coupled zones operate within a narrower thermal operational envelope (e.g., have narrower thermal deltas between different zones of the same type) and thereby yield enhanced performance (e.g., some or all of the non-volatile memory devices experience relatively less memory throttling), ensure a longer operational lifetime and/or ensure a similar operation lifetime of components included in the same thermal zones (e.g., non-volatile memory devices included in the “warm zones”), as detailed herein.

Additionally, the special purpose heat sink(s) (e.g., the thermal islanding heatsink) described herein can allow for heat transfer between the hot components (e.g., controllers, power regulators, etc.), warm components (e.g., flash memory devices, etc.), and/or the cooler components (e.g., DRAM devices, etc.) to be reduced in comparison to the approaches described above, thereby improving error rates, increasing media life, increasing an amount of time between performance of thermal throttling operations, reducing a frequency of media scan operations, and/or mitigating undesirable cross temperature behaviors of the memory sub-system that can arise due to thermal behaviors of the memory sub-system. While the special purpose heat sink of the present disclosure, in connection with the component layouts described herein, are generally described with regard to providing thermal mitigation for components that are deployed along a top portion of the PCB, it is understood that such approaches may alternatively or in addition be deployed with components located on the bottom portion of the PCB of a memory sub-system, which is generally not possible using the monolithic heat sink paradigms of the approaches describe above.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs). In some embodiments, the memory sub-system 100 can be a server such as a rack server.

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory sub-system 110, for example, to write data to the memory sub-system 110 and read data from the memory sub-system 110.

The host system 120 includes a processing device 121. The processing device 121 can be a central processing unit (CPU) that is configured to execute an operating system. In some embodiments, the processing device 121 comprises a complex instruction set computer architecture, such an x86 or other architecture suitable for use as a CPU for a host system 120.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. The memory sub-system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

In some embodiments, the memory sub-system 110 can be resident on a server or other type of computing device such as an IoT device, an edge computing device, etc. As used herein, the term “resident on” refers to something that is physically located on a particular component. For example, the memory sub-system 110 being “resident on” the server refers to a condition in which the hardware that comprises the memory sub-system 110 is physically located on the server. The term “resident on” may be used interchangeably with other terms such as “deployed on” or “located on,” herein.

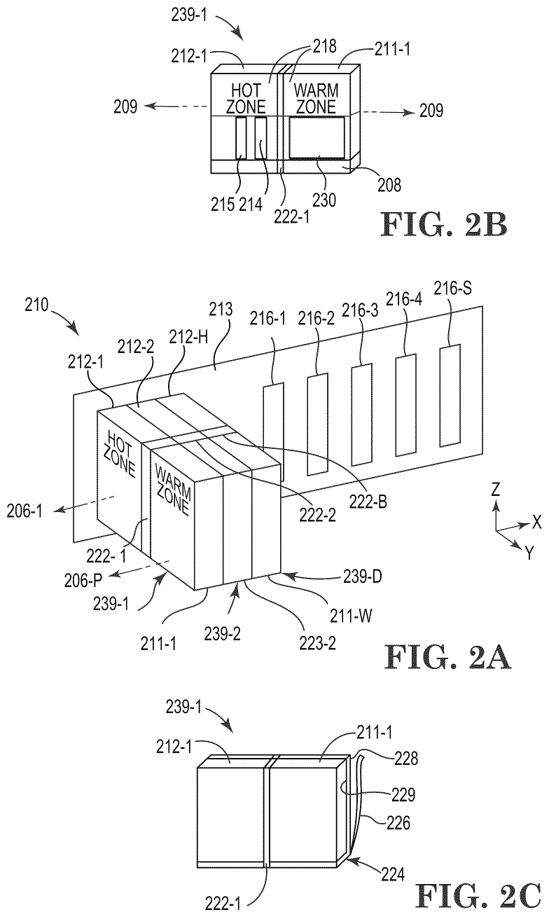

FIG. 2A illustrates a view of an example memory sub-system 210 in accordance with some embodiments of the present disclosure. Although embodiments are not so limited, the example memory sub-system 210 illustrated in FIG. 2A can be a memory sub-system such as an server that has a U.2, U.3, etc. form factor.

The example memory sub-system 210, the memory sub-system 310 and/or the memory sub-system 410, as described herein, can be referred to in the alternative as a “system” or an “apparatus,” herein. As used herein, an “apparatus” or “system” can refer to, but is not limited to, any of a variety of structures or combinations of structures, such as a circuit or circuitry, a die or dice, a module or modules, a device or devices, or a system or systems, for example. For example, the memory sub-system 310 and/or the memory sub-system 410 can include a one or more memory modules (e.g., single in-line memory modules, dual in-line memory modules, etc.). In a number of embodiments, the memory sub-system 310 and/or the memory sub-system 410 can include a multi-chip device. A multi-chip device can include a number of different memory types and/or memory modules (e.g., the memory components(s) 230). Accordingly, the memory sub-system 310 and/or the memory sub-system 410 can include non-volatile or volatile memory on any type of a module. In addition, each of the components (e.g., the controller 215, the power regulation area 214, the memory components(s) 230, as described with respect to FIG. 2B) can be separately referred to herein as an “apparatus” or a “system” given the context of the disclosure.

As mentioned, the memory sub-system 210 can be a server. For instance, the memory sub-system 210 can include a frame defining a plurality of slots in which devices (e.g., memory devices) can be disposed. For instance, the frame can include a surface 213 which can correspond to a server backplate and/or another surface defining a portion of a frame of the server. The surface 213 can be formed of a metal or other thermally conductive material.

For instance, the surface 213 can correspond to a backplate as shown in FIG. 2A. The surface 213 can be formed of a thermally conductive material that is coupled to each of the hot zones. In such instances, a different surface of the frame that is formed of a thermally conductive material can be coupled to each of the warm zones. The different surface can be a front plate that is located on the opposite side of the frame from a back plate, a top plate located between the front plate and the back plate, and/or a bottom plate located between the front plate and the back plate on an opposite side of the frame from the top plate, etc.). In this manner, a first surface (e.g., the surface 213) can be coupled to each of the hot zones while the different surface can be coupled to each of the warm zones. As such, the hot zones can be thermally coupled, the warm zones can be thermally coupled, and yet the hot zones can be thermally isolated from the warm zones, due at least to the hot zone and the warm zones being coupled to different thermally conductive surfaces and the presence of the thermal insulating material between each of the hot zones and the warm zones. Thermally isolating the different zones (e.g., each of the hot zones from each of the warm zones) and yet thermally coupling each of the same type of zone (e.g., each of the warm zones) can promote various aspects of thermal islanding systems, as described herein.

The surface 213 of the frame can define a plurality slots such as a plurality of parallel slots 216-1, 216-2, 216-3, 216-4, . . . 216-S (collectively referred to herein as slots 216). Each of the slots can be configured to receive a memory devices such as memory devices 239-1, 239-2, . . . , 239-D (collectively referred to herein as memory devices 239). When disposed in a slot or a plurality of slots, a surface of the memory devices 239 can be in contact (e.g., in direct contact) with the surface 213 of the frame of the server. As such, each of the memory devices 239 can be thermally coupled together via the surface 213 and thereby permit heat transfer between each of the memory devices 239.

For instance, each of the memory devices 239, as described in greater detail in FIG. 2B, can include a respective heatsink. The heatsink can be in contact with the surface 213. That is, the surface 213 can act as a shared heat sink between which forms a heat transfer interface (e.g., a first heat transfer interface) that is configured to thermally couple together a plurality of the same type of thermal zones (e.g., hot zones or warm zones, etc.). For instance, as illustrated in FIG. 2A, the surface 213 can be a heat transfer interface that is thermally coupled to each hot zone of a plurality of hot zones 212-1, 212-2, . . . 212-H (collectively referred to as hot zones 212). In this way, each of the hot zones 212 can be in thermal communication with other (e.g., adjacent) hot zones to permit the transmission of heat therebetween. Stated differently, each of the plurality of first zones (e.g., hot zones) can be physically adjacent to and thermally coupled with at least one different first zone of the plurality of first zones.

As illustrated in FIG. 2A, a plurality of first zones (e.g., the hot zones 212) can be located along a first plane 206-1 and the plurality of second zones (e.g., the warm zones 211) can be located along a second plane 206-P that is parallel to the first plane. Having each of the first zones co-located along the first plane 206-1 and each of the second zones co-located along the second plane 206-P can promote aspects herein such as promoting heat transfer between a plurality of zones of the same type (e.g., between each of the warm zones). For instance, as illustrated in FIG. 2A, the first plane 206-1 can be parallel with the second plane 206-P and thereby ensure that heat can transfer between the respective zones co-located along a respective plane (e.g., the first plane 206-1), but does not permit heat transfer between different types of zones located which are co-located along a different plane (e.g., the second plane 206-P). That is, each of the plurality of first zones (e.g., the hot zones 212) is physically adjacent to and thermally coupled with at least one different first zone of the plurality of first zones that are co-located along the first plane 206-1. Similarly, each of the plurality of second zones (e.g., the warm zones 211) can be physically adjacent to and thermally coupled with at least one different second zone of the plurality of second zones that are co-located along the second plane 206-P.

As illustrated in the FIG. 2A, a quantity of the plurality of first zones (e.g., the hot zones) can be equal to a quantity of the plurality of second zones (e.g., the warm zones). Having the quantity of a plurality of first type of zones be equal to a quantity of a second type of zones can promote aspects herein such as promoting heat transfer between a plurality of zones of the same type (e.g., between each of the warm zones).

When present, a quantity of a plurality of third type of zones (e.g., cool zones) can be equal to a quantity of each of the first type of the plurality of zones and a quantity of a second type of the plurality of zones. That is, while the memory devices 239 are described in FIG. 2A as including two types of zones, in some embodiments each memory device can include a third zone (e.g., a cool zone). When present, a cool zone (e.g., including volatile memory such as DRAM) in the memory device can be located between the hot zone and the warm zone or can be located on a distal end of either the hot zone or the cool zone, among other possibilities.

Notably, a thermal insulating barrier 222-1 can be present between each hot zone of the plurality of hot zones 212 and each warm zone of the plurality of warm zones 211. In some embodiments, the thermal insulating barrier 222-1 can be present along an entire surface of a hot zone and an entire surface of a warm zone that is most proximate to the surface of the hot zone. For instance, the thermal insulating barrier 222-1 can extend continuously along respective interfaces between each of the hot zones 212 and each of the warm zones 211 thereby forming a continuous thermal insulating barrier 222-1 between each of the warm zones 211 and each of the hot zones 212. Stated differently, each of the hot zones does not directly contact any portion of each of the warm zones. That is, each of a first plurality of zones (e.g., hot zones) can be thermally isolated from each of a second plurality of zones (e.g., a plurality of warm zones), to promote aspects herein.

Alternatively, or in addition, respective thermal zones of the same types in respective memory devices can be thermally coupled together via a different type of heat transfer interface, as described herein. For instance, the respective thermals zones of the memory devices can be thermally coupled together by a heat sink, a heat pipe, a liquid cooling apparatus, or any combination thereof. In any case, thermally coupling together a plurality of thermal zones (e.g., a plurality of warm zones) in different can readily permit heat to be transferred between each of the plurality of thermal zones of the same type. As such, embodiments herein can exhibit an enlarged thermal mass (e.g., relative to an individual thermal zone) and therefore can desirably yield reduced thermal deltas between different zones on the plurality of zone (e.g., due to different workloads of components such as memory devices in the respective thermal zones). Accordingly, approaches herein can yield enhanced performance (e.g., some or all of the non-volatile memory devices experience relatively less memory throttling), ensure a longer operational lifetime, and/or ensure a similar operation lifetime of components in the same type of thermal zone (e.g., non-volatile memory devices included in the “warm zones”), as detailed herein.

In some embodiments, each zone of a plurality of the same type of zones can be the same shape and size (e.g., have the same dimensions). Having each zone of the plurality of zones of the same type of zones be the same shape and size can promote aspects herein such as promoting heat transfer between the plurality of zones of the same type. For instance, in some embodiments each zone of the first plurality of zones of the same type (e.g., hot zones) can be the same size and same shape. Similarly, in some embodiments, each zone of the second plurality of zones (e.g., warm zones) of the same type can be the same size and same shape. In some embodiments, the combined size and shape of the plurality of the first type of zones (e.g., hot zones) can be substantially equal to (e.g., within 5% of) a combined size and shape of the plurality of the second type of zones (e.g., warm zones). For instance, in some embodiments each of the plurality of the first type of zones can be substantially equal in size and shape to each of the plurality of the second type of zones.

While FIG. 2A illustrates a total of two different types of zones (thermal zones) the quantity and/or type of zones can be varied. For instance, in some embodiments a plurality of cool zones can be present in addition to or in place of the plurality of warm zones.

A memory device that is coupled to a respective slot or plurality of slots can be invoked to perform various operations associated with a server such as the storage and/or processing of data. For instance, components in warm zones 211-1, 211-2, . . . , 211-W (collectively referred to herein as warm zones 211) can include non-volatile memory components such as NAND memory components.

FIG. 2B illustrates a view of an example of an individual device 239-1 included in an example of a memory sub-system in accordance with some embodiments of the present disclosure.

As shown in FIG. 2B, the hot zone 212-1 and the warm zone 211-1 within the memory device 239-1 can be located along a plane 209 that is orthogonal to a plane (e.g., the first plane 206-1 and/or the second plane 206-P, as shown in FIG. 2A) along which each of the plurality of hot zones 212 and/or each of the plurality of warm zones 211 are co-located. As shown in FIG. 2B, the hot zone 212-1 of the memory device 239-1 includes a controller 215 and a power regulation area 214. As shown in FIG. 2B, the warm zone 211-1 of the memory device 239-1 includes one or more memory components such as the memory component 230. The memory components 230 can be non-volatile memory components. However, in some embodiments volatile memory components can be present in addition to or in place of the non-volatile memory components.

The components of the memory device 239-1 (e.g., the controller 215, the power regulation area 214, the one or more memory components 230 can be resident on a PCB 208. For instance, each of the controller 215, the power regulation area 214, the memory components 230 may be resident on the same (e.g., top) side of the PCB 208, as illustrated in FIG. 2B. In some embodiments, the controller 215, the power regulation area 214, or both, which are included in each zone of a plurality of first zones (e.g., hot zones) can be resident on a server. Similarly, in some embodiments, the memory components 230 which are included in each zone of a plurality of second zones (e.g., warm zones) can be resident on the server.

In some embodiments, the controller 215, the power regulation area 214, memory component 230 may have access to (e.g., may be coupled to) a heat sink, such as a monolithic heat sink 218 illustrated in FIG. 2B, herein. However, it is understood that in some embodiments, a plurality (e.g., two or more) thermal zones may be employed with one or more thermal insulating barriers in the absence of a heat sink such as a monolithic heat sink.

As mentioned above, certain components (e.g., the controller 215 and the power regulation area 214) of the memory sub-system and the memory devices generally generate more heat during operation than other memory components (e.g., memory components 230). However, conventional thermal dissipation techniques, such as the inclusion of a heat sink tend to spread the heat from the components that generate more heat to the components that generate less heat during operation of the memory sub-system. This can be especially problematic because the components that generate less heat during operation of the memory device (e.g., the memory components 230) can be more susceptible to negative effects as a result of being subjected to heat.

The thermal insulating barrier 222-1 shown in FIG. 2B may extend along the z-axis shown in FIG. 2B through a traditional (e.g., monolithic) heat sink 218. As shown in FIG. 2B, the thermal insulating barrier 222-1 extends through the PCB 208. However, in some embodiments, the thermal insulating barrier 222-1 may be coupled to the top side of the PCB 208. In either case, the thermal insulating barrier 222-1 can provide a physical barrier between the components that generate more heat during operation of the memory sub-system (e.g., the controller 215 and the power regulation area 214) and the components that generate less heat during operation of the memory sub-system (e.g., the memory components 230). The thermal insulating barrier such as thermal insulating barrier 222-1 can be formed from a thermally insulative material (e.g., materials having a relatively low thermal conductivity, such as an acrylic material). Embodiments are not so limited, however, and in some embodiments, the thermal insulating barrier 222-1 can be an air gap (e.g., a region that contains air). As described herein, the thermal insulating barrier can include an air gap and/or a thermally insulting material, such as an acrylic material.

The size (e.g., the height, width, etc.) of the thermal insulating barrier 222-1 can be configured for different applications and/or different expected thermal behaviors of the memory sub-system. For example, the size (e.g., one or more dimensions) of the thermal insulating barrier 222-1 can be larger for a memory sub-system that experiences higher thermal characteristics than for a memory sub-system that experiences lower thermal characteristics. Stated differently, the thermal insulating barrier 222-1 can be larger for memory sub-system architectures that generate a greater amount of heat and/or to offer more protection the memory component 230 than for memory sub-system architectures that generate a lesser amount of heat and/or require less protection the memory component 230.

In a non-limiting example, an apparatus (e.g., the memory sub-system) includes a memory device (e.g., at least one of the memory component 230), a controller 215, and a power regulation area 214. Accordingly, the thermal insulating barrier can be implemented to reduce heat transfer from a portion of the apparatus (e.g., a portion of the apparatus that includes the controller 215 and/or the power regulation area 214) to a portion of the apparatus that includes a non-volatile memory device. In such embodiments, the memory device can be located on a first side of the thermal insulating barrier and the power regulation area and/or the controller is/are on located on a second side of the thermal insulating barrier. Such selective isolation of components can promote additional cooling to be directed to the plurality of warm zones which may include components (memory devices) with a higher temperature sensitivity than the components (e.g., the controller and/or the power regulation area) included in the plurality of hot zones.

For example, as shown in FIG. 2B, et. alibi, the thermal insulating barrier is deployed between i) a hot zone of a heat sink (e.g., an area where components such as the controller 215 and/or the power regulation area 214 that generate the most heat during operation of the apparatus) associated with the apparatus and ii) another area including a warm zone (e.g., an area where components such a non-volatile memory components reside that generate less heat during operation of the apparatus), as described above. As used herein, the term “hot zone” generally refers to an area of the memory sub-system that includes components that generate the most heat in the memory sub-system, a “warm zone” generally refers to an area of the memory sub-system, that includes components that generate less heat than the components in the “hot zone”, and, when present, a “cool zone” generally refers to an area of the memory sub-system that includes components that generate less heat than the components in the “warm zone”. Stated alternatively, a “hot zone” generally refers to an area in which the controller 215 and/or the power regulation area 214 reside, a “warm zone” generally refers to an area in which at least one non-volatile memory device (e.g., NAND) resides, and a “cool zone”, when present, generally refers to an area in which at least one volatile memory device (e.g., DRAM) resides. In some embodiments, the “hot zone” may be thermally coupled to (e.g., adjacent to and/or coupled via a heat pipe and/or liquid cooling) to the “cool zone”, and yet may be thermally isolated (e.g., via the thermal insulating barrier) from the “warm zone”.

As shown in FIG. 2B, the thermal insulating barrier 222-1 can extend through a heat sink 218 associated with the apparatus. For example, at least a portion of the thermal insulating barrier can extend through a heat sink 218 associated with the apparatus. Further, the heat sink 218 can be one or more heat sinks (e.g., a plurality of heat sinks) and the thermal insulating barrier can be disposed between at least two of the plurality of heat sinks.

As described above, the controller 215 and the power regulation area 214 are disposed on a top portion of the PCB 208 and similarly, the non-volatile memory component 230 is disposed on a top portion of the PCB 208. In such embodiments, a “warm zone” of the heat sink (and/or the thermal insulating barrier) may be in physical contact with at least the one of the non-volatile memory devices and a “hot zone” of the heatsink may be in physical contact with the controller and the power regulation area.

As shown in FIG. 2B, the memory device 239-1 includes an individual thermal insulating barrier 222-1. Similarly, each of the other memory devices 239 can include an individual thermal insulating barrier such as the thermal insulating barrier 222-2 in the memory device 239-2 and the thermal insulating barrier 222-B in the memory device 239-D, as shown in FIG. 2A. Thus, a thermal insulating barrier between the plurality of hot zone and the plurality of warm zones can be formed of a collection of individual insulating barriers that are each located at a respective interfaces between each of the hot zones and each of the warm zones. That is, the power regulation area 214 and the controller 215 are co-located within an individual “hot zone” on the same side of the PCB 208. Having the power regulation area 214 and the controller can be co-located within an individual “hot zone” on the same side of the PCB in a given memory device may permit use of fewer thermal insulating barriers (e.g., use of an individual thermal insulating barrier, as detailed below) and/or may otherwise promote various aspects herein. For instance, this can allow for improved thermal mitigation to be provided to the memory components 230, which can lead to improved memory device performance and/or extended memory device lifetime in comparison to the previous approaches described herein.

In this non-limiting example, the thermal insulating barrier is formed entirely through the monolithic heat sink such that the thermal insulating barrier extends beyond an area defined by the monolithic heat sink. Stated alternatively, the thermal insulating barrier can be formed such that the thermal insulating barrier extends through the monolithic heat sink and the PCB 208 to provide thermal mitigation to components of the memory sub-system that are disposed on a top portion of the PCB 208, as described above. Embodiments are not so limited, however, and the thermal insulating barrier can be formed such that the thermal insulating barrier extends above the monolithic heat sink (e.g., in a larger lateral dimension with respect to the z-axis shown in at least or the thermal insulating barrier can be formed such that the thermal insulating barrier extends below the monolithic heat sink (e.g., in a smaller lateral dimension with respect to the z-axis as shown in FIG. 2A).

FIG. 2C illustrates a view of another example of an individual memory device 239-1 included in an example of a memory sub-system in accordance with some embodiments of the present disclosure. The memory device 239-1 is analogous to the memory device 239-1 illustrated in FIG. 2B, but with the addition of a thermal tray 224.

The thermal tray 224 is formed of a conductive material such as a metal. The surfaces of the thermal tray 224 can define a space (e.g., a recess) in which a device such as the memory device 239-1 can be disposed. While illustrated as having an individual thermal tray corresponding to an individual device (e.g., the memory device 239-1) in some embodiments the thermal tray can be configured to define spaces in which a plurality of devices can be disposed. While illustrated in FIG. 2C as individual thermal tray, in some embodiments, each of the devices 239 can be disposed in a corresponding thermal tray.

Notably, the thermal insulating barrier 222-1 can separate the thermal tray 224 into zones. The zones of the thermal tray 224, as illustrated in FIG. 2C, can correspond to (e.g., be the same size, shape, and quantity as) the zones in the memory device 239-1. Thus, the thermal tray 224 can be configured to thermally couple together zones (e.g., warm zones) of the same type that are located in different devices. For instance, the thermal tray can thermally couple together a plurality of a first type of zone (e.g., the hot zone 212-1 in the memory device 239-1 and the hot zone 212-2 in the memory device 239-2, etc.) and can also thermally couple together a plurality of a second type of zone (e.g., the warm zone 211-1 in the memory device 239-1 and the warm zone 211-2 in the memory device 239-2, etc.), and yet at least due to the presence of the thermal insulating barrier 222-1 can thermally isolate each of the plurality of the first type of zone from each of the plurality of second type of zone. For instance, heat can transfer between a first (e.g., back) surface 228 and a second (e.g., front) surface of thermal tray 224 but may not transfer between different types of zones (e.g., between the hot zone 212-1 and/or the warm zone 211-1) in the memory device 239-1 and/or the thermal tray 224. That is, the surface of the warm zone in the memory device 239-1 can be in direct contact with the corresponding warm zone in the thermal tray 224 and similarly the surface of the hot zone in the memory device 239-1 can be in direct contact with the surface of the hot zone in the thermal tray, yet the hot zone in the thermal tray can be thermally isolated from the warm zone in the thermal tray.

In some embodiments, the thermal tray 224 can include a retention latch such as the retention latch 226. As illustrated in FIG. 2C, the retention latch 226 can be comprised of an arm that is coupled to an extends from a surface of the thermal tray 224. In any case, the retention latch 226 can be configured to couple the a device to the thermal tray 224. For instance, the retention latch 226 can be disposed (e.g., by a spring force and/or by another mechanical force) to impart a force (e.g., the is substantially orthogonal to the surface 228 and/or the surface 229) on a device disposed in a space defined by the thermal tray 224 and thereby retain the memory device in the thermal tray 224. In some embodiments, each thermal tray 224 can include at least one retention latch. In FIG. 2C, the retention latch associated with the memory device 239-1 is omitted for ease of illustration. However, in some embodiments the thermal tray 224 may be employed in the absence of a retention latch and/or may be employed using a different type of retention mechanism (e.g., pin/socket, etc.).

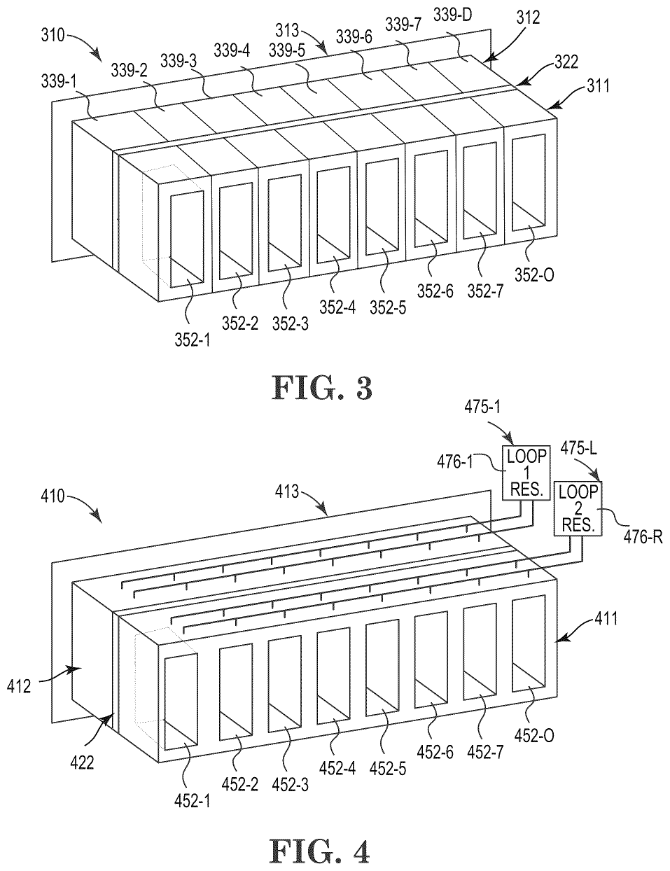

FIG. 3 illustrates a view of another example of a memory sub-system 310 in accordance with some embodiments of the present disclosure. The memory sub-system 310 is analogous to the memory sub-system 210 illustrated in FIG. 2, but has each of the slots in a surface 313 populated with a corresponding memory device 339-1, 339-2, 339-3, 339-4, 339-5, 339-6, 339-7, . . . 339-D (collectively referred to herein as memory devices 339).

The memory devices 339 can each include at least one memory component slot which is configured to receive a memory component such as a non-volatile memory component, a volatile memory component, or a combination thereof. For instance, the memory devices 339 can include memory component slots 352-1, 352-2, 352-3, 352-4, 352-5, 352-6, 352-7, . . . , 352-O (corresponding to memory component slots 452-1, 452-2, 452-3, 452-4, 452-5, 452-6, 452-7, . . . 452-O, shown in FIG. 4) configured to receive a non-volatile memory component within a respective warm zone of the memory device. Thus, the memory components can reside in the respective warm zones, but not in the respective hot zones of the memory devices, for instance, as illustrated in FIG. 2B.

In some embodiments, each of the individual memory devices can include a respective hot zone and a respective warm zone. The plurality of respective hot zones can be represented collectively as hot zones 312. The plurality of respective warm zones can be represented collectively as warm zones 311. The respective hot zones can be separated from the respective warm zones by a thermal insulating barrier, as described herein. For instance, a continuous thermal insulating barrier 322 can be disposed between each of the hot zones 312 and each of the warm zones 311. Thus, the hot zones 312 can be thermally coupled together, the warm zones 311 can be thermally coupled together, and yet the hot zones 312 can be thermally isolated from the warm zones 312. For instance, each of the hot zones 312 can be thermally coupled together, each of the warm zones 311 can be thermally coupled together, and yet each of the hot zones 312 can be thermally isolated from each of the warm zones 311, to promote aspects herein.

FIG. 4 illustrates a view of another example of a memory sub-system 410 in accordance with some embodiments of the present disclosure. The memory sub-system 410 is analogous to the memory sub-system 310 illustrated in FIG. 3, but includes dedicated cooling system associated with the different types of zones in the memory sub-system 410.

As shown in FIG. 4, the memory sub-system 410 can include a first heat transfer interface in the form of a first liquid cooling apparatus 475-1 that is coupled to each of the hot zones 412. For instance, the first liquid cooling apparatus 475-1 can be coupled to a portion of a respective heat sink associated with each of the plurality of hot zones, among other possibilities. Similarly, the memory sub-system 410 can include a second heat transfer interface in the form of a second liquid cooling apparatus 475-L that is coupled to each of the warm zones 411. For instance, the second liquid cooling apparatus can be coupled to a portion (e.g., a warm zone) of a respective heat sink associated with each of the warm zones of the memory devices (e.g., the memory devices 339 as shown in FIG. 3). As shown in FIG. 4, the first liquid cooling apparatus 475-1 is separate from (e.g., not connected nor thermally coupled to) the second liquid cooling apparatus 475-L. For instance, the first liquid cooling reservoir 476-1 is separate from the second liquid cooling reservoir 476-R. Having the first liquid cooling apparatus 475-1 be separate from the second liquid cooling apparatus can promote aspects herein such as providing differing degrees of cooling to different zones in the memory devices.

For instance, the memory sub-system 410 may have a plurality of different types of thermal zones each including a plurality of zones (e.g., a plurality of hot zones 412 and a plurality of warm zones 411). As illustrated in FIG. 4, the memory sub-system 410 can include a plurality of liquid cooling reservoirs. The respective liquid cooling reservoirs may be associated with one or more thermal zones. For instance, a first liquid cooling reservoir 476-1 may be associated with each of the plurality of hot zones 412, while a second liquid cooling reservoir 476-R may be associated with each of a plurality of warm zones 411 (e.g., which include memory components such as non-volatile memory components). The liquid cooling reservoirs 476-1, 476-R may include water or another fluid that can be circulated from the liquid cooling reservoirs through the respective thermal zones associated therewith to cool the respective plurality of same type of thermal zones. That is, in contrast to some previous approaches that may employ a single liquid cooling reservoir to cool all components (e.g., controller, power regulation circuitry and memory devices) in an apparatus, in the present disclosure each reservoir is associated with (cools) some but not all of the zones and components of the apparatus.

Additionally, the thermal insulating barrier 422 can be present to block the flow of heat between the different types of zones associated with the different liquid cooling reservoirs. As a result of the presence of the plurality of liquid (water) cooling reservoirs and the thermal insulating barrier 422, memory sub-system 410 performance can be improved in contrast to other approaches that do not employ a plurality of liquid cooling reservoirs associated with different types of thermal zones and/or a thermal insulating barrier therebetween. For instance, the memory sub-system 410 may realize less thermal throttling (e.g., longer period of operation in an absence of thermal throttling and/or improved performance (e.g., improved performance attributable to operation of temperature sensitive memory components at lower temperatures, etc.).

In some embodiments, a memory sub-system such as the memory sub-system 410 can include a heat pipe. As used herein, a heat pipe refers to a heat-transfer device that employs phase transitions (e.g., between the liquid phase and gas phase) to transfer heat between two solid interfaces.

In some embodiments, a first heat pipe (not illustrated) may thermally couple one or more zones of a plurality of a first type of zones (e.g., one or more of a plurality of hot zones) and a second heat pipe (not illustrated) may thermally couple one or more zones of a plurality of second type of zones (e.g., one or more of a plurality of warm zones). That is, the first heat pipe can be configured to transport heat between one or more of the first type of zones and similarly the second heat pipe can be configured to transport heat between one or more of the second type of zones. During operation of the apparatus, the first type of zones (e.g., hot zones) are characterized by having a higher temperature than the second type of zones (e.g., a warm zone).

For instance, the first heat pipe may transfer heat from a hot zone including a controller and/or the power regulation area to a different hot zone including a different controller and/or a different power regulation area. Similarly, the second heat pipe may transfer heat from a warm zone including one or more non-memory components to a different warm zone including one or more non-volatile memory components. In such examples, the first heat pipe may transfer heat from one hot zone to a different hot zone but not to the components in a different type of zone (e.g., a warm zone). Similarly, the second heat pipe may transfer heat from one warm zone to a different warm zone but not to the components in a different type of zone (e.g., hot zone). That is, a heat pipe can be employed as a thermal interface between a plurality of the same type of zones (e.g., hot zones or warm zones), in some embodiments. The heat pipes can be employed as a thermal interface in addition to or in place of the other types of thermal interfaces mentioned above.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a plurality of first zones including a controller, a power regulation area, or both;
a first heat transfer interface coupled to the plurality of first zones;
a plurality of second zones including memory devices;
a second heat transfer interface coupled to the plurality of second zones; and
a thermal insulating barrier deployed between the plurality of first zones and the plurality of second zones.

2. The apparatus of claim 1, wherein the plurality of first zones are located along a first plane, and wherein the plurality of second zones are located along a second plane that is parallel to the first plane.

3. The apparatus of claim 1, wherein a total quantity of the plurality of first zones is equal to a total quantity of the plurality of second zones.

4. The apparatus of claim 1, wherein:
the controller, the power regulation area, or both, of each of plurality of first zones are resident on a server; and
the memory devices of the plurality of second zones are resident on the server.

5. The apparatus of claim 1, wherein each zone of the plurality of first zones is the same size and same shape.

6. The apparatus of claim 1, wherein the thermal insulating barrier comprises an air gap or a thermally insulting material, or both.

7. The apparatus of claim 1, wherein each zone of the plurality of second zones is the same size and shape.

8. The apparatus of claim 1, wherein each of the plurality of first zones is physically adjacent to and thermally coupled with at least one different first zone of the plurality of first zones.

9. The apparatus of claim 1, wherein each of the plurality of second zones is physically adjacent to and thermally coupled with at least one different second zone of the plurality of second zones.

10. An apparatus, comprising:
a surface of frame defining a plurality of parallel slots;
a plurality of devices disposed in respective slots of the plurality of parallel slots, wherein each device of the plurality of devices includes:
a controller, power regulation circuitry, or both, resident in a first zone;
a memory device coupled resident in a second zone; and
a thermal insulating barrier extending between the first zone and the second zone to thermally isolate the first zone from the second zone;
a first heat transfer interface coupled to the first zone; and
a second heat transfer interface coupled to the second zone.

11. The apparatus of claim 10, wherein the thermal insulating barrier is a continuous thermal insulating barrier extending along a plane between a first surface of the first zone and a second surface of the second zone, wherein the second surface of the second zone is a surface of the second zone that is most proximate to the first surface of the first zone.

12. The apparatus of claim 11, wherein the first zone and the second zone are located along a plane that is orthogonal to the plane between the first surface of the first zone and the second surface.

13. The apparatus of claim 10, wherein, during operation of the apparatus the first zone is characterized by having a higher temperature than the second zone.

14. A system comprising:
a plurality of hot zones including a controller and a power regulation area;
a first heat transfer interface coupled to each hot zone of the plurality of hot zones;
a plurality of warm zones including non-volatile memory devices;
a second heat transfer interface coupled to each warm zone of the plurality of warm zones; and
a thermal insulating barrier that defines an interface between respective surfaces of each hot zone of the plurality of hot zones and respective surfaces of each warm zone of the plurality of warm zones.

15. The system of claim 14, wherein the first heat transfer interface and the second heat transfer interface each further comprises a heat sink, a heat pipe, a liquid cooling apparatus, or any combination thereof.

16. The system of claim 14, wherein the thermal insulating barrier comprises a thermally insulting material.

17. The system of claim 14, wherein the thermal insulating barrier is form of a plurality of individual insulating barriers that are each located at a respective interfaces between each of the plurality of hot zones and each of the plurality of warm zones.

18. The system of claim 14, wherein:
the first heat transfer interface is a first liquid cooling apparatus that is coupled to a heat sink associated with each of the plurality of hot zones; and
the second heat transfer interface is a second liquid cooling apparatus that is coupled a heat associated with each of the plurality of warm zones, and wherein the second liquid cooling apparatus separate from the first liquid cooling apparatus.

19. The system of claim 18, wherein the first liquid cooling apparatus is coupled to a first liquid cooling reservoir.

20. The system of claim 19, wherein the second liquid cooling apparatus is coupled to a second liquid cooling reservoir that is separate from the first liquid cooling reservoir.
